(19) United States
(12) Patent Application Publication
(10) Pub. No.: US 2019/0190652 A1
(43) Pub. Date: Jun. 20, 2019

(54) Encoding Rate Adjustment Method and Terminal

(71) Applicant: Huawei Technologies Co., Ltd., Shenzhen (CN)

(72) Inventors: Li Shen, Beijing (CN); Jiwu Liu, Beijing (CN); Jun Zhou, Shanghai (CN)

(21) Appl. No.: 16/327,970

(22) PCT Filed: Aug. 26, 2016
(86) PCT No.: PCT/CN2016/096945

§ 371 Date: Feb. 25, 2019

(51) Int. Cl. H04L 1/00; H03M 13/00; H04W 4/02; H04L 1/20

(52) U.S. Cl. CPC H04L 1/0042; H04L 1/203; H04W 4/027; H03M 13/635

(57) ABSTRACT

An encoding rate adjustment method and a terminal. An encoding rate adjustment method includes determining, by the terminal, whether a moving speed of the terminal exceeds a preset speed threshold, and adjusting, by the terminal, a first encoding rate to a second encoding rate if the moving speed of the terminal exceeds the speed threshold, where the second encoding rate is determined based on an encoding rate that is used by the terminal in a previous data communication.

### CROSS-REFERENCE TO RELATED APPLICATIONS

This application is a national stage of International Application No. PCT/CN2016/096945, filed on Aug. 26, 2016, which is hereby incorporated by reference in its entirety.

### TECHNICAL FIELD

This application relates to the communications field, and in particular, to an encoding rate adjustment method and a terminal.

### BACKGROUND

In mobile communication, a terminal negotiates a high encoding rate with the other party for data communication. A higher encoding rate indicates a larger data volume generated in communication.

However, a terminal in a high-speed moving state is usually in a communications network having a poor network signal coverage capability, and data of a large data volume generated when the terminal is at a high encoding rate cannot be transmitted in time. Consequently, the other communication party receives abnormal data, for example, noise or stalling in voice communication, and communication quality is reduced.

### SUMMARY

This application provides an encoding rate adjustment method and a terminal, to resolve a technical problem that communication quality of a terminal is poor when the terminal performs data communication in high-speed movement.

A first aspect of this application provides an encoding rate adjustment method, including the following steps: determining, by a terminal, whether a moving speed exceeds a speed threshold, and if the moving speed exceeds the speed threshold, adjusting, by the terminal, a first encoding rate to a second encoding rate determined based on an encoding rate that is used by the terminal in a previous data communication. It may be learned that before data communication is performed, if it is found that the moving speed of the terminal is higher than the preset speed threshold, an encoding rate used in this data communication may be determined based on the encoding rate used in the previous data communication, and the encoding rate is corrected in time. In this way, generation of a large data volume is prevented and abnormality such as data loss or erroneous transmission is avoided when the data communication is performed at an unduly high encoding rate, and poor communication experience of a user caused by an unduly low encoding rate is avoided.

A second aspect of this application provides a terminal, including the following structures: a memory storing an application program and data generated during running of the application program, and a processor. The processor executes the application program to: determine whether a moving speed of the terminal exceeds a preset speed threshold, and if the moving speed of the terminal exceeds the speed threshold, adjust a first encoding rate to a second encoding rate determined based on an encoding rate that is used by the terminal in a previous data communication. It may be learned that before the terminal performs data communication, if it is found that the moving speed of the terminal is higher than the preset speed threshold, an encoding rate used in this data communication may be determined based on the encoding rate used in the previous data communication, and the encoding rate is corrected in time. In this way, generation of a large data volume is prevented and abnormality such as data loss or erroneous transmission is avoided when the data communication is performed at an unduly high encoding rate, and poor communication experience of a user caused by an unduly low encoding rate is avoided.

In an implementation, the second encoding rate is determined based on whether the moving speed of the terminal in the previous data communication exceeds the speed threshold, and if the moving speed of the terminal in the previous data communication does not exceed the speed threshold, a preset encoding rate is determined as the second encoding rate, or if the moving speed of the terminal in the previous data communication exceeds the speed threshold, a bit error rate of the previous data communication is obtained, and then the second encoding rate is determined based on a value relationship between the bit error rate and a preset bit error threshold. Therefore, when the moving speed of the terminal in the previous data communication does not exceed the speed threshold, the preset low encoding rate is determined as the second encoding rate, and the encoding rate is decreased in time, so that the terminal does not generate a large data volume at a low encoding rate, and even in a communications network having a poor network signal coverage capability, the terminal can still transmit data to the other party in time. In this way, abnormal cases such as data loss or erroneous transmission are avoided. For example, stalling and noise in voice communication are avoided. Therefore, communication quality of data communication is improved. When the moving speed of the terminal in the previous data communication exceeds the speed threshold, the second encoding rate is determined based on the bit error rate of the previous data communication, and the encoding rate is better corrected in time. In this way, generation of a large data volume is prevented and abnormality such as data loss and erroneous transmission is avoided when data communication is performed at an unduly high encoding rate, and poor communication experience of the user caused by an unduly low encoding rate is avoided.

In an implementation, the preset bit error threshold includes a first bit error threshold and a second bit error threshold, and the first bit error threshold is greater than the second bit error threshold. Therefore, the bit error threshold is classified into two threshold levels, and a value of the bit error rate of the terminal in the previous data communication is compared with a value of a bit error threshold, so that the second encoding rate is corrected in time, and the encoding rate is better corrected in time. In this way, generation of a large data volume is prevented and abnormality such as data loss and erroneous transmission is avoided when data communication is performed at an unduly high encoding rate, and poor communication experience of the user caused by an unduly low encoding rate is avoided.

In an implementation, the determining the second encoding rate based on a value relationship between the bit error rate and a preset bit error threshold includes: if the bit error rate is greater than the first bit error threshold and the encoding rate used in the previous data communication is a minimum encoding rate, determining, as the second encoding rate, the encoding rate used in the previous data communication, or if the bit error rate is greater than the first bit error threshold and the encoding rate used in the previous data communication is not a minimum encoding rate, decreasing the encoding rate used in the previous data communication to a third encoding rate, and determining the third encoding rate as the second encoding rate, or if the bit error rate is less than the second bit error threshold, increasing the encoding rate used in the previous data communication to a fourth encoding rate, and determining the fourth encoding rate as the second encoding rate. Therefore, the second encoding rate is adjusted level by level based on the bit error rate of the terminal in the previous data communication, so that a second encoding rate obtained after the adjustment better matches the moving speed of the terminal, and the encoding rate is better corrected in time. In this way, generation of a large data volume is prevented and abnormality such as data loss and erroneous transmission is avoided when data communication is performed at an unduly high encoding rate, and poor communication experience of the user caused by an unduly low encoding rate is avoided.

### BRIEF DESCRIPTION OF THE DRAWINGS

To describe the technical solutions in the embodiments of this application or in the prior art more clearly, the following briefly describes the accompanying drawings required for describing the embodiments or the prior art. Apparently, the accompanying drawings in the following description show some embodiments of this application, and a person of ordinary skill in the art may still derive other drawings from these accompanying drawings without creative efforts.

FIG. 1 is a schematic diagram of communication negotiation performed between terminals;

FIG. 2, FIG. 3, and FIG. 4 are flowcharts of implementation of an encoding rate adjustment method according to Embodiment 1 of this application; and

FIG. 5 is a schematic structural diagram of a terminal according to an embodiment of this application.

### DETAILED DESCRIPTION OF ILLUSTRATIVE EMBODIMENTS

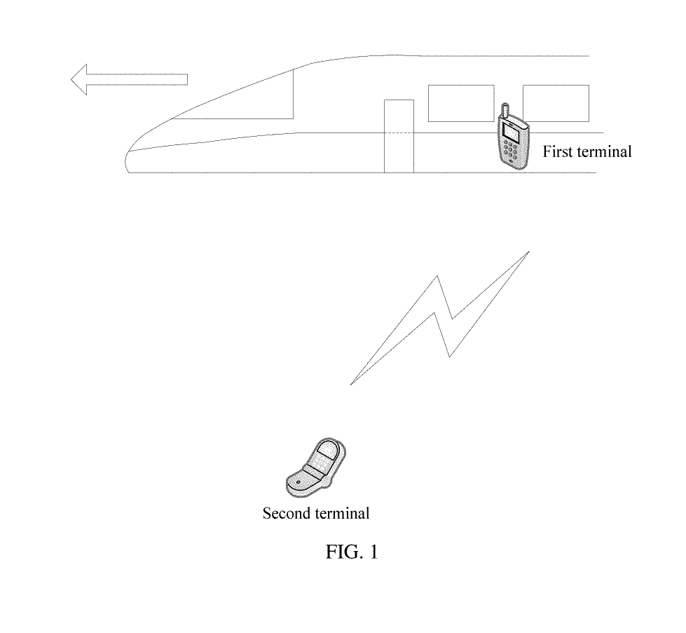

FIG. 1 is a schematic diagram of communication negotiation performed between terminals. Using voice communication between a first terminal and a second terminal as an example, when the first terminal in high-speed movement needs to perform data communication with the second terminal, the first terminal negotiates an encoding rate with the second terminal based on a voice encoding rate supported by the first terminal, and then establishes voice communication based on the negotiated encoding rate.

For example, an adaptive multi-rate-wideband speech codec (AMR-WB) in the terminal has nine rates: 6.6 kilobits per second (Kbps), 8.85 Kbps, 12.65 Kbps, 14.25 Kbps, 15.85 Kbps, 18.25 Kbps, 19.85 Kbps, 23.05 Kbps, and 23.85 Kbps, and the terminal usually uses the encoding rate of 23.85 Kbps during negotiation. The terminal generates a larger voice data volume at a higher encoding rate. Therefore, in a same communications network, a terminal having a higher encoding rate has better communication quality.

However, a signal coverage capability of a communications network in which a terminal in high-speed movement is located is usually poor. Consequently, a large data volume generated when the terminal is at an unduly high encoding rate cannot be transmitted to the second terminal in time, and abnormality such as loss or erroneous transmission of some data occurs in data received by the second terminal, causing stalling or noise in voice communication and affecting communication quality.

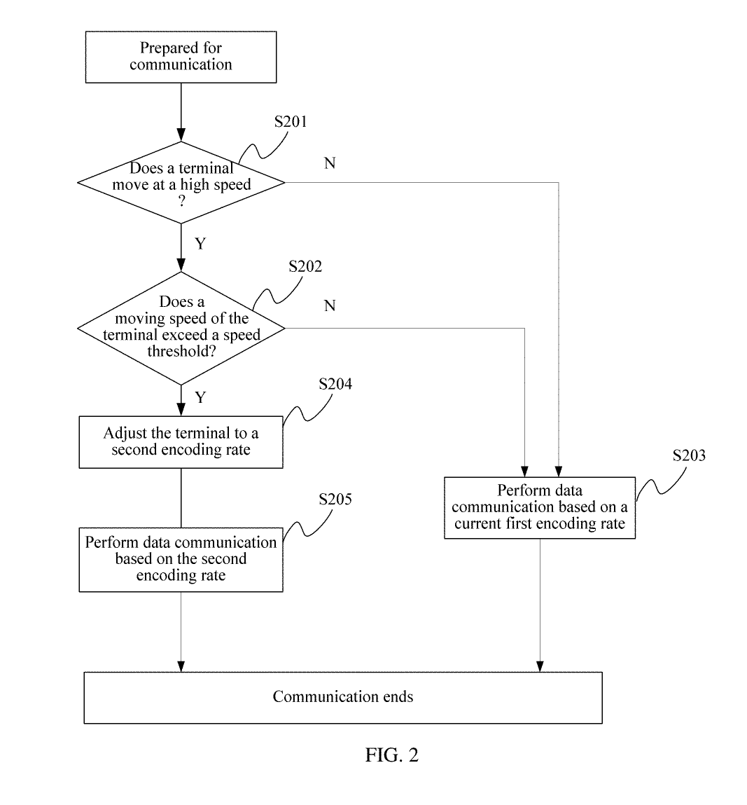

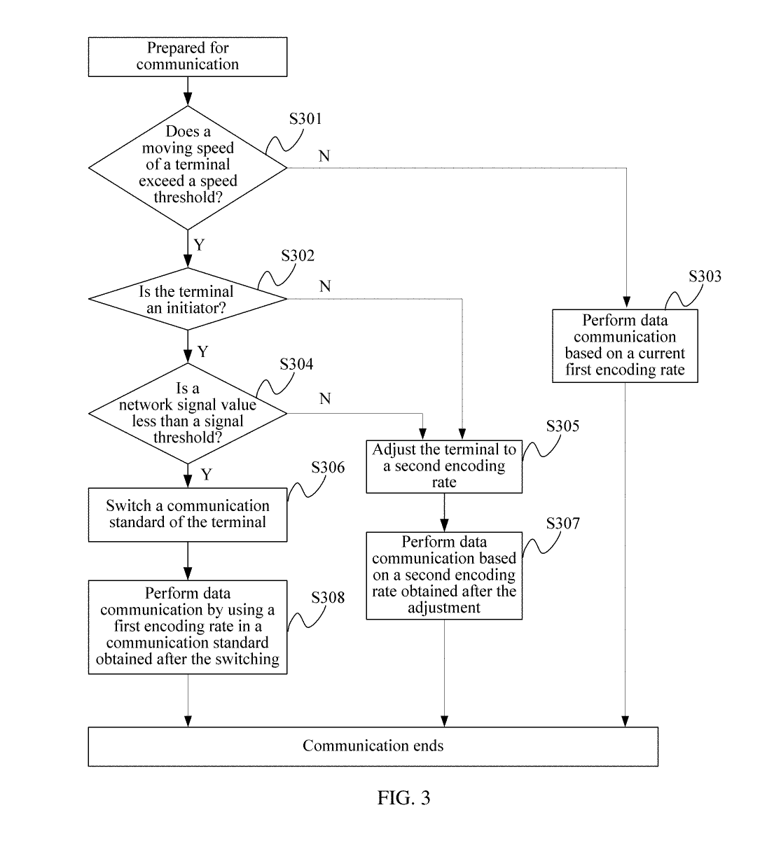

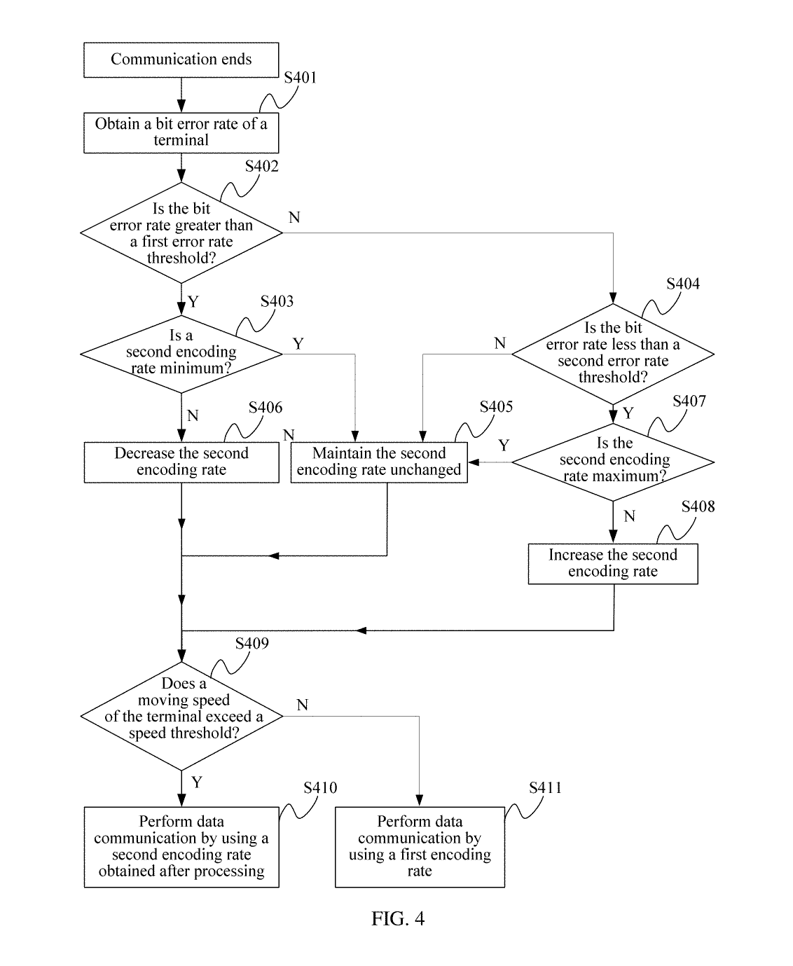

FIG. 2 is a flowchart of implementation of an encoding rate adjustment method according to an embodiment of this application in which data communication of terminals on a high-speed railway is used as an example. This embodiment is applied to the first terminal or the second terminal shown in FIG. 1, to resolve a technical problem of poor quality of data communication of terminals in high-speed movement. In FIG. 2, when the terminal is prepared for data communication, the terminal performs the following steps.

S201: Determine whether a terminal is in a high-speed moving state, and if the terminal is in the high-speed moving state, perform S202, or if the terminal is not in the high-speed moving state, perform S203.

Using a terminal on a high-speed railway in high-speed movement as an example, the terminal may determine whether the terminal is in the high-speed moving state in a plurality of manners, to determine whether the terminal is in a high-speed railway riding state.

For example, the terminal determines whether the terminal is in the high-speed moving state by using content of a field highspeedflag in a system message that is fed back by a communications network in which the terminal is located. The field highspeedflag is used to indicate a moving state of the terminal. For example, when the field highspeedflag is true, it indicates that the terminal is in a high-speed moving state, that is, in a riding state in a high-speed railway dedicated network.

Whether the terminal is in the high-speed railway riding state may alternatively be determined in another manner: The terminal determines whether the terminal is in the high-speed moving state by using information collected by an internal sensor hub (sensor hub). For example, the terminal first uses the sensor hub to collect sensing parameters, such as an acceleration, a degree of inclination, and an atmospheric pressure that are collected by various sensors such as an acceleration sensor, a gyroscope, and a barometer. After the sensing parameters are integrated, a status of the terminal, for example, motionless, walking, running, bicycling, or riding, is obtained by combining a general algorithm such as a classifier and a decision tree with specific implementation, so that whether the terminal is in the high-speed moving state, that is, in the riding state in the high-speed railway dedicated network, can be determined.

Provided that whether the terminal is currently in the high-speed moving state is determined in S201, S202 of determining whether a moving speed of the terminal exceeds a speed threshold needs to be further performed. If the terminal is not in the high-speed moving state, a specific moving speed does not need to be determined.

S202: Determine whether a moving speed exceeds a preset speed threshold, and if the moving speed exceeds the speed threshold, perform S204, or if the moving speed does not exceed the speed threshold, perform S203.

In this embodiment, the terminal may obtain the moving speed of the terminal by using a GPS and a sensor hub, and then the terminal determines, based on the obtained moving speed, whether the moving speed of the terminal exceeds the speed threshold.

Alternatively, the terminal may calculate the moving speed of the terminal by using a corresponding algorithm when a modem MODEM of the terminal is in a link state, and then the terminal determines whether the moving speed exceeds the speed threshold.

That the MODEM is in the link state means that the terminal is in a data transmission state, such as a call state or a short message service message transmission state, different from that the MODEM is in a non-link state. That the MODEM is in the non-link state means that the terminal is in a stand-by state.

The speed threshold herein may be, for example, 200 kilometers per hour.

S203: Perform data communication based on a current first encoding rate.

S204: Adjust the current first encoding rate of the terminal to a preset second encoding rate, and perform S205.

S205: Perform data communication based on a second encoding rate obtained after the adjustment.

Whether the second encoding rate herein is less than the first encoding rate may be determined based on historical data or empirical data, and both the second encoding rate and the first encoding rate are encoding rates that can be supported by a codec in the terminal.

For example, the codec in the terminal is an AMR-WB. The first encoding rate is 23.05 Kbps. In this embodiment, when the terminal determines that the terminal is in the high-speed moving state and a train speed exceeds 200 km/h, the encoding rate of the terminal is decreased to 12.65 Kbps, 14.25 Kbps, or the like in this case.

That is, in this embodiment, before the terminal performs data communication, if it is found that the terminal is in the high-speed railway riding state, the encoding rate of the terminal may be decreased, so that the terminal performs data communication based on an encoding rate obtained after the adjustment. In this way, the terminal does not generate a large data volume at a low encoding rate, and even in a communications network having a poor network signal coverage capability, the terminal can still transmit data to the other party in time. In this way, abnormal cases such as data loss or erroneous transmission are avoided. For example, stalling and noise in voice communication are avoided. Therefore, communication quality of data communication is improved and objectives of this embodiment are implemented.

As shown in FIG. 3, FIG. 3 is a flowchart of implementation of another encoding rate adjustment method according to an embodiment. When a terminal determines that a moving speed exceeds a speed threshold, the terminal may further adjust a corresponding communication mode by determining a role played by the terminal in communication, to improve communication quality. The terminal in FIG. 1 adjusts an encoding rate by performing the following steps in FIG. 3.

S301: Determine whether a moving speed exceeds a speed threshold, and if the moving speed exceeds the speed threshold, perform S302, or if the moving speed does not exceed the speed threshold, perform S303.

In this embodiment, for implementation of which the terminal determines whether the moving speed exceeds the speed threshold, refer to content of related steps in FIG. 2, and details are not described herein again.

S302: Determine whether a terminal is an initiator of data communication, and if the terminal is the initiator, perform S304, or if the terminal is not the initiator, perform S305.

In data communication, there are following communication features: If the terminal is a calling party, the terminal may select an appropriate communication standard for data communication, or if the terminal is a called party, a communication standard of the terminal is determined based on a communications network in which the terminal is currently located when the terminal receives a data communication request, and the communication standard cannot be changed or switched. Therefore, in this embodiment, the terminal first determines whether the terminal is an initiator or a receiver of data communication.

For example, in voice communication, the terminal determines whether the terminal is a calling party or a called party in the voice communication.

S303: Perform data communication based on a current first encoding rate.

S304: Determine whether a network signal value of a communications network in which the terminal is located is less than a preset signal threshold, and if the network signal value is less than the signal threshold, perform S306, or if the network signal value is not less than the signal threshold, perform S305.

The network signal value herein is a parameter value that can represent a network communication capability of a communications network, for example, a data transmission rate value of the communications network or a signal strength value of the communications network. For example, when the network signal value is less than the preset signal threshold, it indicates that a data transmission rate of the communications network is low in this case.

S305: Adjust the current first encoding rate of the terminal to a preset second encoding rate, and perform S307.

S306: Switch a communication standard of the terminal, and perform S308.

In this embodiment, the communication standard may be switched in a manner of single radio voice call continuity (SRVCC).

S307: Perform data communication based on a second encoding rate obtained after the adjustment.

S308: Perform data communication by using a first encoding rate in a communication standard obtained after the switching.

Based on the communication features in the foregoing descriptions, for example, the communications network in which the terminal is initially located is a 4G network. In this embodiment, when the terminal determines that the moving speed of the terminal exceeds the speed threshold, the terminal may adjust the communication mode by determining whether the terminal plays a role of a calling party or a called party in communication, thereby improving communication quality.

For example, when a network signal value of a 4G network in which the terminal is currently located is less than the signal threshold, in other words, when the data transmission rate is low, it may be selected that data communication is performed after the communication standard of the terminal is switched to a 2G or 3G mode, to improve communication quality of data communication.

Alternatively, with reference to the implementations in the foregoing embodiments, when the network signal value of the 4G network in which the terminal is currently located is not less than the signal threshold, in other words, when the data transmission rate is high (“high” herein refers to a case in which a relative network signal value is less than the signal threshold), only the encoding rate of the terminal needs to be decreased, and the terminal may still use a current communication standard, thereby improving communication quality.

In this embodiment, when the network communication capability of the communications network in which the terminal is located is good, the terminal may not directly switch the communication standard, and decrease the encoding rate instead to some extent, to reduce a data volume that needs to be transmitted. When the terminal performs data communication in a high-speed moving state, the terminal can perform data transmission in time to improve communication quality.

Therefore, compared with an implementation solution in the prior art in which the communication quality is improved by switching the communication standard, in this embodiment, the communication quality is improved by decreasing the encoding rate, so that solutions of improving the communication quality are enriched, and requirements of a user on the communication quality are met.

In FIG. 2 or FIG. 3, when the moving speed of the terminal exceeds the speed threshold, the terminal adjusts the encoding rate used in data communication to a preset low second encoding rate, to improve the communication quality.

However, during actual implementation, there may be a case in which the second encoding rate is inaccurate. For example, the encoding rate is still high or the encoding rate is adjusted to be unduly low. Therefore, the second encoding rate needs to be corrected.

To correct the second encoding rate, FIG. 4 is a flowchart of another encoding rate adjustment method according to an embodiment of this application. This method is applicable to any terminal shown in FIG. 1, and the terminal corrects the second encoding rate by performing steps shown in FIG. 4. FIG. 4 may include the following steps.

S401: After a terminal performs data communication by using a second encoding rate and the data communication ends, obtain a bit error rate of the data communication performed by using the second encoding rate.

S402: Determine whether the bit error rate is greater than a preset first bit error threshold, and if the bit error rate is greater than the first bit error threshold, perform S403, or if the bit error rate is not greater than the first bit error threshold, perform S404.

S403: Determine whether the second encoding rate is a minimum encoding rate supported by the terminal, and if the second encoding rate is the minimum encoding rate supported by the terminal, perform S405, or if the second encoding rate is not the minimum encoding rate supported by the terminal, perform S406.

S404: Determine whether the bit error rate is less than a preset second bit error threshold, where the second bit error threshold is less than the first bit error threshold, and if the bit error rate is less than the second bit error threshold, perform S407, or if the bit error rate is not less than the second bit error threshold, perform S405.

The bit error rate described in this specification may also be understood as a bit error proportion, that is, a proportion of a quantity of error bits or lost bits to a total quantity of bits.

S405: Maintain the second encoding rate unchanged as an encoding rate used for a next data communication that is performed by the terminal, and perform S409.

S406: Decrease the second encoding rate to obtain an encoding rate used for a next data communication that is performed by the terminal, and perform S409.

Decreasing the second encoding rate herein may be decreasing the second encoding rate to a rate that is in the encoding rate supported by the terminal and that is lower than a current second encoding rate by at least one rate gear. The rate gear herein may be understood as an encoding rate level supported by the terminal, and each encoding rate level is used as a rate gear.

Using a codec AMR-WB in the terminal as an example, the terminal supports the following encoding rates: 6.6 Kbps, 8.85 Kbps, 12.65 Kbps, 14.25 Kbps, 15.85 Kbps, 18.25 Kbps, 19.85 Kbps, 23.05 Kbps, and 23.85 Kbps.

In an implementation, decreasing the second encoding rate by the terminal may be decreasing the encoding rate to an encoding rate lower than the current encoding rate by one rate gear.

For example, the current second encoding rate of the terminal is 12.65 Kbps, and if the bit error rate is greater than the first bit error threshold, the terminal decreases the second encoding rate to 8.85 Kbps. Alternatively, the current second encoding rate of the terminal is 19.85 Kbps, and if the bit error rate is greater than the first bit error threshold, the terminal decreases the second encoding rate to 18.25 Kbps.

In another implementation, decreasing the second encoding rate by the terminal may be decreasing the encoding rate to an encoding rate lower than the current encoding rate by two rate gears.

For example, the current second encoding rate of the terminal is 23.05 Kbps, and if the bit error rate is greater than the first bit error threshold, the terminal decreases the second encoding rate to 18.25 Kbps. Alternatively, the current second encoding rate of the terminal is 6.6 Kbps, the encoding rate in this case is the minimum encoding rate supported by the terminal, and even if the bit error rate is still greater than the first bit error threshold, the terminal does not decrease the second encoding rate.

S407: Determine whether the second encoding rate is a maximum encoding rate supported by the terminal, and if the second encoding rate is the maximum encoding rate supported by the terminal, perform S405, or if the second encoding rate is not the maximum encoding rate supported by the terminal, perform S408.

It should be noted that during actual application, if a moving speed of the terminal exceeds a speed threshold this time, and a moving speed of the terminal in a previous data communication also exceeds the speed threshold, the encoding rate of the terminal in the previous data communication is usually an encoding rate decreased to particular extent, and is usually not the maximum encoding rate supported by the terminal. Therefore, in this embodiment, during actual application, S407 may be omitted and S408 is performed when it is determined in S404 that the bit error rate is less than the second bit error threshold.

S408: Increase the second encoding rate to obtain an encoding rate used for a next data communication that is performed by the terminal, and perform S409.

Increasing the second encoding rate herein may be increasing the second encoding rate to a rate that is in the encoding rate supported by the terminal and that is higher than the current second encoding rate by at least one rate gear.

In an implementation, increasing the second encoding rate by the terminal may be increasing the encoding rate to an encoding rate higher than the current encoding rate by one rate gear.

For example, the current second encoding rate of the terminal is 12.65 Kbps, and if the bit error rate is less than the second bit error threshold, the terminal increases the second encoding rate to 14.25 Kbps. Alternatively, the current second encoding rate of the terminal is 19.85 Kbps, and if the bit error rate is less than the second bit error threshold, the terminal increases the second encoding rate to 23.05 Kbps.

In another implementation, increasing the second encoding rate by the terminal may be increasing the encoding rate to an encoding rate higher than the current encoding rate by two rate gears.

For example, the current second encoding rate of the terminal is 23.05 Kbps, and when the bit error rate is less than the second bit error threshold and an encoding rate higher than 23.05 Kbps by one gear is already the maximum encoding rate supported by the terminal, the terminal directly increases the second encoding rate to the maximum encoding rate supported by the terminal, that is, 23.85 Kbps. Alternatively, the current second encoding rate of the terminal is 23.85 Kbps, and in this case, the encoding rate is the maximum encoding rate supported by the terminal, and the terminal does not increase the second encoding rate.

S409: Determine whether a moving speed exceeds a speed threshold, and if the moving speed of the terminal exceeds the speed threshold, perform S410, or if the moving speed of the terminal does not exceed the speed threshold, perform S411.

That the terminal determines whether the moving speed exceeds the speed threshold herein is a step performed when the terminal is about to perform data communication. That is, before performing data communication each time, the terminal determines whether a current moving speed of the terminal exceeds the speed threshold.

S410: Perform data communication by using a second encoding rate obtained after the processing as an encoding rate used in this data communication, for example, an encoding rate obtained after S405, S406, or S408.

S411: Perform data communication by using a first encoding rate.

The first bit error threshold and the second bit error threshold may be set based on requirements on communication quality. For example, the first bit error threshold may be set to 5%, and the second bit error threshold may be set to 1%. When the bit error rate is greater than 5%, it indicates that the encoding rate of the terminal is low, and when the bit error rate is less than 1%, it indicates that the encoding rate of the terminal is high, and therefore, the encoding rate needs to be correspondingly adjusted.

It should be noted that the procedure shown in FIG. 4 is an implementation procedure in which data communication is performed after the encoding rate of the terminal is adjusted to the second encoding rate, the encoding rate of the terminal is corrected based on this data communication, and a second encoding rate obtained after the correction is used for a next data communication. Such a solution is applicable to a scenario in which the terminal corrects the encoding rate each time before the terminal performs data communication.

That is, each time before performing data communication, the terminal determines whether a current moving speed of the terminal exceeds the speed threshold, and when the terminal determines that the current moving speed of the terminal exceeds the speed threshold, the terminal performs data communication by using the second encoding rate. The second encoding rate herein is a second encoding rate obtained after correction processing, and the correction solution herein depends on a bit error rate of a latest data communication of which the moving speed of the terminal exceeds the speed threshold.

For example, the data communication performed by the terminal by using the second encoding rate is used as the first data communication. After the first data communication ends, the second encoding rate used in the latest data communication in which the moving speed exceeds the speed threshold is corrected based on the bit error rate by using the solution shown in FIG. 4. Specifically, the terminal obtains the bit error rate of the first data communication. If the bit error rate is greater than the first bit error threshold, the terminal decreases the encoding rate used in the first data communication by one rate gear, to obtain an encoding rate used for the second data communication, or if the bit error rate is less than the second bit error threshold of the first bit error threshold, the terminal increases the encoding rate used in the first data communication to obtain an encoding rate used for the second data communication.

Before needing to perform the second data communication, the terminal first determines whether the moving speed of the terminal exceeds the speed threshold. If the moving speed of the terminal exceeds the speed threshold, the terminal directly performs the second data communication by using the encoding rate used for the second data communication obtained in the foregoing description. If the moving speed of the terminal does not exceed the speed threshold, the terminal continues to use the original first encoding rate to perform the second data communication. If the moving speed of the terminal exceeds the speed threshold again, with reference to the solution shown in FIG. 2 or FIG. 3, the encoding rate used by the terminal in the data communication is adjusted again, and an encoding rate obtained after the adjustment uses the encoding rate used for the second data communication. After the second data communication ends, the second encoding rate used in the latest data communication in which the moving speed exceeds the speed threshold is corrected based on the bit error rate by using the solution shown in FIG. 4. Specifically, the terminal obtains the bit error rate of the second data communication. If the bit error rate is greater than the first bit error threshold, the terminal decreases the encoding rate used in the second data communication by one rate gear to obtain an encoding rate used for the third data communication. If the bit error rate is less than the second bit error threshold, the terminal increases the encoding rate used in the second data communication to obtain an encoding rate used for the third data communication.

By analogy, each time after the data communication ends, the terminal corrects the encoding rate based on the bit error rate of the data communication, and uses an encoding rate obtained after the correction as an encoding rate used for a next data communication in which the moving speed exceeds the speed threshold. Therefore, the encoding rate is adjusted to a most appropriate one when the terminal performs data communication in movement whose moving speed exceeds a threshold, so that the bit error rate is maintained between the first bit error threshold and the second bit error threshold, thereby improving communication quality of data communication performed by the terminal when the terminal is in the movement whose moving speed exceeds the threshold.

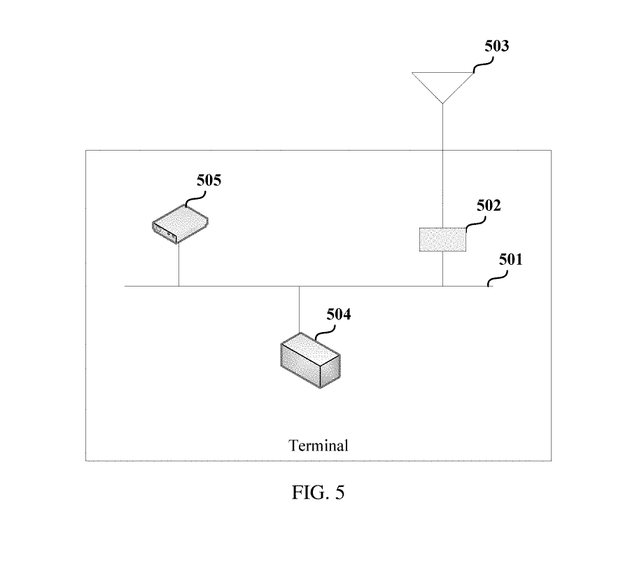

FIG. 5 is a schematic structural diagram of the terminal shown in FIG. 1, and the terminal shown in FIG. 5 may include the following structures, including a bus 501, configured to connect all components in the terminal, a communications interface 502 and an antenna 503, where the antenna 503 is connected to the bus 501 by using the communications interface 502, a memory 504, connected to the bus 501 and configured to store an application program and data generated during running of the application program, and a processor 505, configured to execute the application program to implement functions of determining whether a moving speed of the terminal exceeds a preset speed threshold, and, if the moving speed of the terminal exceeds the speed threshold, adjusting a first encoding rate of the terminal to a second encoding rate, where the second encoding rate is determined based on an encoding rate that is used by the terminal in a previous data communication, and the antenna 503 uses the second encoding rate for data communication.

An implementation structure of the terminal is shown in FIG. 5. For a function implemented by each structure in the terminal, refer to the foregoing implementations, and details are not described herein again.

The embodiments in this specification are all described in a progressive manner, for same or similar parts in the embodiments, refer to these embodiments, and each embodiment focuses on a difference from other embodiments.

1. An encoding rate adjustment method, wherein the method is applied to a terminal, and comprises:
determining, by the terminal, whether a moving speed of the terminal exceeds a preset speed threshold; and
adjusting, by the terminal, a first encoding rate to a second encoding rate if the moving speed of the terminal exceeds the speed threshold, wherein the second encoding rate is determined based on an encoding rate that is used by the terminal in a previous data communication.

2. The method according to claim 1, further comprising determining the second encoding rate, wherein the determining of the second encoding rate comprises:
determining, by the terminal, whether the moving speed of the terminal in the previous data communication exceeds the speed threshold; and
performing at least one of:
determining, by the terminal, a preset encoding rate as the second encoding rate if the moving speed of the terminal in the previous data communication does not exceed the speed threshold; or
obtaining, by the terminal, a bit error rate of the previous data communication and determining the second encoding rate based on a value relationship between the bit error rate and a preset bit error threshold if the moving speed of the terminal in the previous data communication exceeds the speed threshold.

3. The method according to claim 2, wherein the preset bit error threshold comprises a first bit error threshold and a second bit error threshold, and the first bit error threshold is greater than the second bit error threshold.

4. The method according to claim 2, wherein the determining the second encoding rate based on a value relationship between the bit error rate and a preset bit error threshold comprises:
if the bit error rate is greater than the first bit error threshold and the encoding rate used in the previous data communication is a minimum encoding rate, determining, as the second encoding rate, the encoding rate used in the previous data communication.

5. A terminal, wherein the terminal comprises:
a memory and
a processor;
wherein the memory is configured to store an application program and data generated during running of the application program; and
wherein the processor is configured to execute the application program to implement functions of:
determining whether a moving speed of the terminal exceeds a preset speed threshold, and
adjusting a first encoding rate to a second encoding rate if the moving speed of the terminal exceeds the speed threshold, wherein the second encoding rate is determined based on an encoding rate that is used by the terminal in a previous data communication.

6. The terminal according to claim 5, wherein the processor is further configured to determine the second encoding rate by:
determining whether the moving speed of the terminal in the previous data communication exceeds the speed threshold; and
performing at least one of:
determining a preset encoding rate as the second encoding rate if the moving speed of the terminal in the previous data communication does not exceed the speed threshold; or
obtaining a bit error rate of the previous data communication and determining the second encoding rate based on a value relationship between the bit error rate and a preset bit error threshold if the moving speed of the terminal in the previous data communication exceeds the speed threshold.

7. The terminal according to claim 6, wherein the preset bit error threshold comprises a first bit error threshold and a second bit error threshold, and the first bit error threshold is greater than the second bit error threshold.

8. The terminal according to claim 6, wherein the processor determining the second encoding rate based on the value relationship between the bit error rate and the preset bit error threshold comprises:
performing at least one of:
if the bit error rate is greater than the first bit error threshold and the encoding rate used in the previous data communication is a minimum encoding rate, determining, as the second encoding rate, the encoding rate used in the previous data communication
determining the third encoding rate as the second encoding rate; or

9. The method according to claim 2, wherein the determining the second encoding rate based on a value relationship between the bit error rate and a preset bit error threshold comprises:
if the bit error rate is greater than the first bit error threshold and the encoding rate used in the previous data communication is not a minimum encoding rate, decreasing the encoding rate used in the previous data communication to a third encoding rate, and determining the third encoding rate as the second encoding rate.

10. The method according to claim 2, wherein the determining the second encoding rate based on a value relationship between the bit error rate and a preset bit error threshold comprises:
if the bit error rate is less than the second bit error threshold, increasing the encoding rate used in the previous data communication to a fourth encoding rate, and determining the fourth encoding rate as the second encoding rate.

11. The method according to claim 2, wherein the determining the second encoding rate based on a value relationship between the bit error rate and a preset bit error threshold comprises:
if the bit error rate is less than the second bit error threshold and the encoding rate used in the previous data communication is a maximum encoding rate, determining, as the second encoding rate, the encoding rate used in the previous data communication.

12. The terminal according to claim 6, wherein the processor determining the second encoding rate based on the value relationship between the bit error rate and the preset bit error threshold comprises:
if the bit error rate is greater than the first bit error threshold and the encoding rate used in the previous data communication is not a minimum encoding rate, decreasing the encoding rate used in the previous data communication to a third encoding rate, and determining the third encoding rate as the second encoding rate.

13. The terminal according to claim 6, wherein the processor determining the second encoding rate based on the value relationship between the bit error rate and the preset bit error threshold comprises:
if the bit error rate is less than the second bit error threshold, increasing the encoding rate used in the previous data communication to a fourth encoding rate, and determining the fourth encoding rate as the second encoding rate.

14. The terminal according to claim 6, wherein the processor determining the second encoding rate based on the value relationship between the bit error rate and the preset bit error threshold comprises:
if the bit error rate is less than the second bit error threshold and the encoding rate used in the previous data communication is a maximum encoding rate, determining, as the second encoding rate, the encoding rate used in the previous data communication.

15. A terminal, wherein the terminal comprises:
a memory; and
a processor;
wherein the memory stores code and data, and the processor executes the code in the memory, so that the terminal performs:
determining whether a moving speed of the terminal exceeds a preset speed threshold, and
adjusting a first encoding rate to a second encoding rate if the moving speed of the terminal exceeds the speed threshold, wherein the second encoding rate is determined based on an encoding rate that is used by the terminal in a previous data communication.

16. The terminal according to claim 15, wherein the determining the second encoding rate comprises:
determining whether the moving speed of the terminal in the previous data communication exceeds the speed threshold;
determining a preset encoding rate as the second encoding rate if the moving speed of the terminal in the previous data communication does not exceed the speed threshold; and
obtaining a bit error rate of the previous data communication and determining the second encoding rate based on a value relationship between the bit error rate and a preset bit error threshold if the moving speed of the terminal in the previous data communication exceeds the speed threshold.

17. The terminal according to claim 16, wherein the preset bit error threshold comprises a first bit error threshold and a second bit error threshold, and the first bit error threshold is greater than the second bit error threshold.

18. The terminal according to claim 16, wherein the determining the second encoding rate based on the value relationship between the bit error rate and the preset bit error threshold comprises:
if the bit error rate is greater than the first bit error threshold and the encoding rate used in the previous data communication is a minimum encoding rate, determining, as the second encoding rate, the encoding rate used in the previous data communication.

19. The terminal according to claim 16, wherein the determining the second encoding rate based on the value relationship between the bit error rate and the preset bit error threshold comprises:
if the bit error rate is greater than the first bit error threshold and the encoding rate used in the previous data communication is not a minimum encoding rate, decreasing the encoding rate used in the previous data communication to a third encoding rate, and determining the third encoding rate as the second encoding rate.

20. The terminal according to claim 16, wherein the determining the second encoding rate based on the value relationship between the bit error rate and the preset bit error threshold comprises:
if the bit error rate is less than the second bit error threshold, increasing the encoding rate used in the previous data communication to a fourth encoding rate, and determining the fourth encoding rate as the second encoding rate.
